(19) United States
(12) Patent Application Publication
(10) Pub. No.: US 2004/0152237 A1
(43) Pub. Date: Aug. 5, 2004

(54) Method for forming flip-chip bumps of a semiconductor chip

(76) Inventor: Simon Shiau, Hsinchu Hsien (TW)

Correspondence Address: PRO-TECHTOR INTERNATIONAL, 20755 Norada Court, Saratoga, CA, 95070-3018, US

(21) Appl. No.: 10/358,504

(22) Filed: Feb. 4, 2003

(51) Int. Cl. H01L 21/44

(52) U.S. Cl. 438/108; 438/613

(57) ABSTRACT

A method for forming flip-chip bumps of a semiconductor chip includes the steps of: providing a wafer including a plurality of chips, each of which having a plurality of bonding pads and a trace region; providing a protection layer to cover each of the trace regions of the chips; forming the bumps on the bonding pads of each chip, respectively; and removing the protection layer on each of the chips.

### BACKGROUND OF THE INVENTION

1. Field of the Invention

The invention relates to a method for forming flip-chip bumps of a semiconductor chip, and in particular to a method for forming flip-chip bumps and preventing each chip from being damaged or contaminated.

2. Description of the Related Art

The processes for packaging a semiconductor chip may include a wire bonding process or a flip-chip bonding process. In the wire bonding process, metal wires are provided to electrically connect bonding pads of the chip to the substrate and then an encapsulant is provided to encapsulate the chip. However, in the wire bonding process, a wire-bonding region has to be left on the substrate. Therefore, the packaged chip has a greater volume. In the flip-chip bonding process, bumps are formed on each bonding pad of the chip, and then the bumps are directly and electrically connected to the substrate without the metal wires serving as signal transmission media between the chip and the substrate. Therefore, no wire-bonding region has to be left in advance on the substrate, and the packaged chip may have a smaller volume and achieve the miniaturized requirement.

The conventional method for forming the bumps on the chip is performed by forming metal bumps on each bonding pad of the chip by way of etching or screen printing after traces are formed on the wafer. During the etching or screen printing process, however, chippings or particles of the metal material may contaminate the trace region of the chip and may damage or contaminate the chip.

### SUMMARY OF THE INVENTION

An object of the invention is to provide a method for forming flip-chip bumps of a semiconductor chip and preventing the chip from being contaminated.

The invention achieves the above-mentioned object by providing a method for forming flip-chip bumps. The method includes the steps of: providing a wafer including a plurality of chips, each of which having a plurality of bonding pads and a trace region; providing a protection layer to cover each of the trace regions of the chips; forming the bumps on the bonding pads of each chip, respectively; and removing the protection layer on each of the chips. Hence, when the bumps are formed on each chip, the trace region is protected by the protection layer without being contaminated or damaged.

### BRIEF DESCRIPTION OF THE DRAWINGS

FIG. 1 is a schematic illustration showing a condition in a first step of the method for manufacturing flip-chip bumps of a semiconductor chip of the invention.

FIG. 2 is a schematic illustration showing a condition in a second step of the method for manufacturing the flip-chip bumps of the semiconductor chip of the invention.

FIG. 3 is a schematic illustration showing a condition in a third step of the method for manufacturing the flip-chip bumps of the semiconductor chip of the invention.

FIG. 4 is a schematic illustration showing a condition in a fourth step of the method for manufacturing the flip-chip bumps of the semiconductor chip of the invention.

### DETAILED DESCRIPTION OF THE INVENTION

The method for forming flip-chip bumps of the invention will be described in the following. The method includes the following steps.

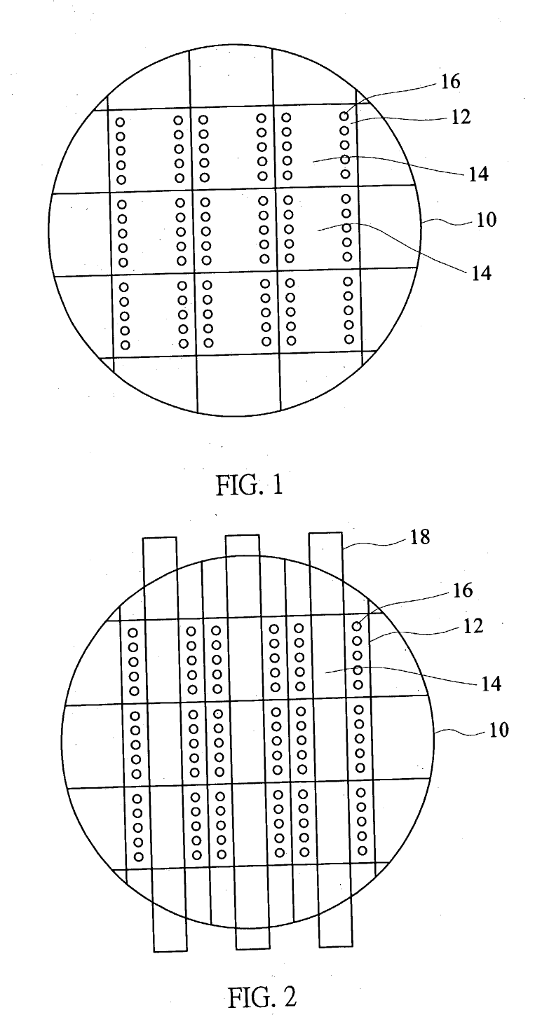

First, as shown in FIG. 1, a wafer 10 including a plurality of chips 12 is first provided. A trace region 14 is formed in a central portion of each chip 12, and bonding pads 16 are formed around the trace region 14.

Next, as shown in FIG. 2, a protection layer 18, such as a long tape having a width slightly greater than that of the trace region 14 of the chip 12, is adhered to the chip 12 to cover the trace region 14.

Then, as shown in FIG. 3, the bonding pads 16 of each chip 12 are etched or screen-printed to form bumps 20. In this process, the particles or chippings generated during the formation of the bumps 20 may be separated by the protection layer 18 and cannot contaminate or damage the trace region 14 of the chip 12. Thus, it is possible to protect the chip 12 from being damaged.

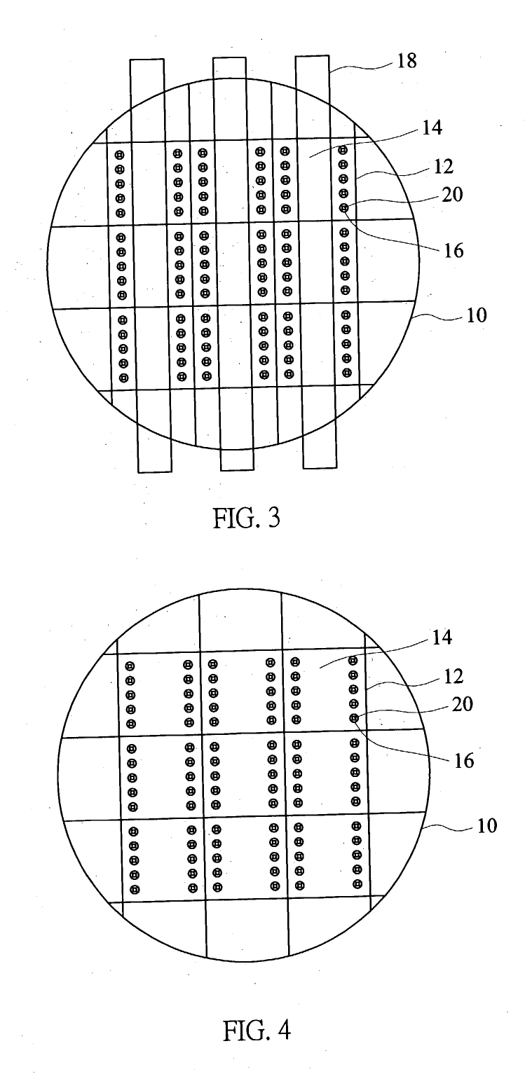

Next, as shown in FIG. 4, the protection layer 18 on the trace region 14 of the chip 12 is removed after the bumps 20 of the chip 12 are formed.

Consequently, during the process for forming the flip-chip bumps 20, the chip 12 is free from being contaminated or damaged, and the production yield of the chip 12 may be effectively improved.

Furthermore, when a semiconductor chip is packaged, the method for forming the bumps on the chip of the invention may be applied to the flip chip packaging process so that the product may be miniaturized. In addition, the wire bonding process and machine may be omitted, and the manufacturing cost may be effectively reduced accordingly.

While the invention has been described by way of an example and in terms of a preferred embodiment, it is to be understood that the invention is not limited to the disclosed embodiment. To the contrary, it is intended to cover various modifications. Therefore, the scope of the appended claims should be accorded the broadest interpretation so as to encompass all such modifications.

What is claimed is:

1. A method for forming flip-chip bumps of a semiconductor chip, comprising the steps of:
providing a wafer including a plurality of chips, each of which having a plurality of bonding pads and a trace region;
providing a protection layer to cover each of the trace regions of the chips;
forming the bumps on the bonding pads of each chip, respectively; and
removing the protection layer on each of the chips.

2. The method according to claim 1, wherein the protection layer is a tape.

3. The method according to claim 1, wherein the step of forming the bumps is performed by way of etching or screen-printing.
